(19) United States
(12) Patent Application Publication
(10) Pub. No.: US 2016/0293870 A1
(43) Pub. Date: Oct. 6, 2016

(54) DISPLAY DEVICE

(71) Applicant: Japan Display Inc., Tokyo (JP)

(72) Inventor: Takuya NAKAGAWA, Tokyo (JP)

(21) Appl. No.: 15/082,496

(22) Filed: Mar. 28, 2016

(30) Foreign Application Priority Data
Mar. 30, 2015 (JP) 2015-069500

(51) Int. Cl. H01L 51/00; G02F 1/1339; H01L 51/52; G02F 1/1333

(52) U.S. Cl. CPC H01L 51/0097; G02F 1/133305; G02F 1/1339; H01L 51/5246

(57) ABSTRACT

A display device includes a first insulating substrate, a second insulating substrate, and a sealant. The first insulating substrate flexible and has a display area provided with an image display function. The second insulating substrate is smaller than the first insulating substrate and covers the display area. The sealant is disposed around the display area and fixes the first insulating substrate and the second insulating substrate together. The first insulating substrate has a bent portion that is adjacent to an edge of the second insulating substrate and a return portion that is folded back away from the second insulating substrate.

### CROSS-REFERENCE TO RELATED APPLICATION

The present application claims priority from Japanese application JP2015-069500 filed on Mar. 30, 2015, the content of which is hereby incorporated by reference into this application.

### BACKGROUND OF THE INVENTION

1. Field of the Invention

The present invention relates to a display device.

2. Description of the Related Art

Some liquid crystal display devices control the orientation of liquid crystals using switching elements, such as transistors, to display images. Some display panels, such as liquid crystal panels filled with liquid crystals, each include, for example, a glass substrate. JP 2006-024530 A discloses a display device that includes a first glass substrate, a second glass substrate disposed facing the first glass substrate, and a plastic film disposed on at least one of the first and second glass substrates.

### SUMMARY OF THE INVENTION

Some of the display devices each have a display area and a frame area. If the display panel were formed with a flexible substrate and folded back to narrow the frame area, the display area might be strained.

Therefore, it is an object of the present invention to provide a narrow frame display device having a less strained display area.

A display device according to an aspect of the present invention includes a first insulating substrate, a second insulating substrate, and a sealant. The first insulating substrate is flexible and has a display area provided with an image display function. The second insulating substrate is smaller than the first insulating substrate and covers the display area. The sealant is disposed around the display area and fixes the first and second insulating substrates together. The first insulating substrate has a bent portion that is adjacent to an edge of the second insulating substrate and a return portion that is folded back away from the second insulating substrate.

### BRIEF DESCRIPTION OF THE DRAWINGS

FIG. 1 is a perspective view of a display device according to a first embodiment of the present invention;

FIG. 2 is a plan view of a display panel according to the first embodiment of the present invention;

FIG. 3 is a side view of the display panel according to the first embodiment of the present invention;

FIG. 4 is a cross-sectional view of the display panel according to the first embodiment of the present invention;

FIG. 5 is a cross-sectional view of a display panel according to a modification of the first embodiment of the present invention;

FIG. 6 is a side view of a display panel according to a second embodiment of the present invention;

FIG. 7 is a side view of a display panel according to a third embodiment of the present invention; and

FIG. 8 is a side view of a display panel according to a modification of the third embodiment of the present invention.

### DETAILED DESCRIPTION OF THE INVENTION

The following describes embodiments of the present invention with reference to the accompanying drawings. The disclosure herein is merely an example, and appropriate modifications coming within the spirit of the present invention, which are easily conceived by those skilled in the art, are intended to be included within the scope of the invention as a matter of course. In some drawings, the widths, the thicknesses, the shapes, and other characteristics of various parts are schematically shown for clarity of illustration, as compared to actual configurations. However, such schematic drawings are merely examples and are not intended to limit the present invention. In the present specification and drawings, some elements identical or similar to those previously shown are denoted by the same reference signs as the previously-shown elements, and thus are not described in detail herein as appropriate.

### First Embodiment

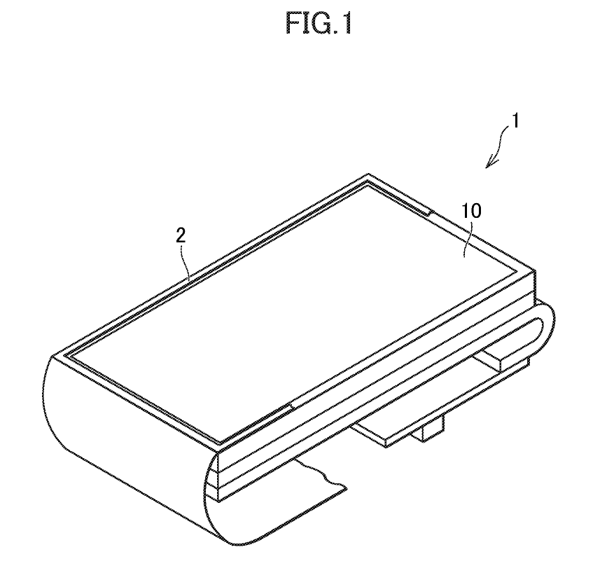

FIG. 1 is a perspective view of a display device 1 according to a first embodiment of the present invention. The display device 1 includes a frame 2 and a display panel 10 fixed inside the frame 2. The display panel 10 is fixed with its edge folded back, as described later.

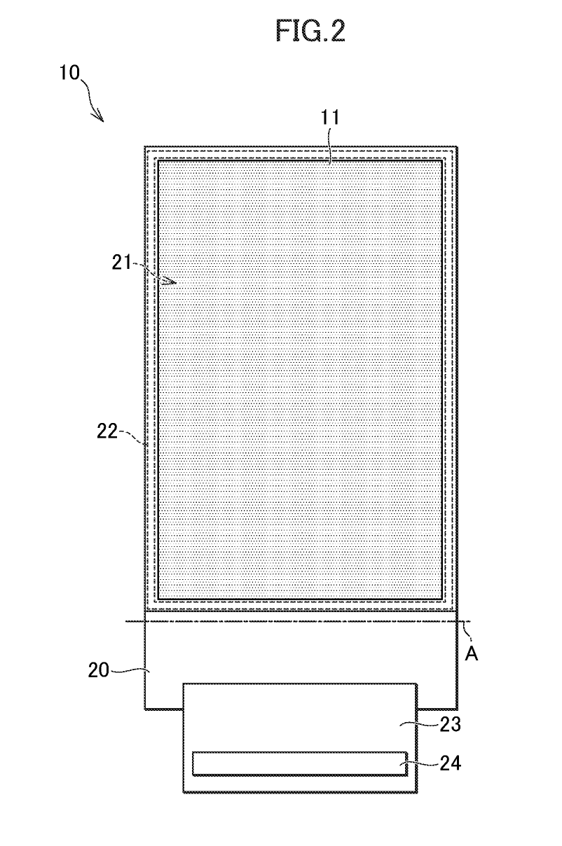

FIG. 2 is a plan view of the display panel 10 according to the first embodiment of the present invention. FIG. 2 shows the display panel 10 before being incorporated into the frame 2. The display panel 10 includes a first insulating substrate 20, a second insulating substrate 21, and a sealant 22. The first insulating substrate 20 is flexible and has a display area provided with an image display function. The second insulating substrate 21 is smaller than the first insulating substrate 20 and covers the display area 11. The sealant 22 is disposed around the display area 11 and fixes the first insulating substrate 20 and the second insulating substrate 21 together. The first insulating substrate 20 is an insulating substrate that forms what is called a thin film transistor (TFT) substrate (array substrate) and is made of a flexible material, such as polyimide. The second insulating substrate 21 is what is called a counter substrate and is made of glass or a hard resin. The hard resin is what is called an organic glass, such as polycarbonate resin or an acrylic resin. The second insulating substrate 21 is less flexible than the first insulating substrate 20. The second insulating substrate 21 needs to be at least more rigid, that is, less flexible than the first insulating substrate 20, and is preferably so rigid that deformation of the display panel 10 under its own weight falls within several percent.

The display panel 10 has a flexible printed circuit (FPC) 23 joined to an edge of the first insulating substrate 20. The flexible printed circuit 23 has a driver integrated circuit (IC) 24 mounted thereon. The flexible printed circuit 23 may have other electronic circuits mounted thereon. The sealant 22 may double as a spacer that keeps a constant gap between the first insulating substrate 20 and the second insulating substrate 21. When the sealant 22 is also used as a spacer, the distance between the first insulating substrate 20 and the second insulating substrate 21 can be adjusted by selecting the thickness of the sealant 22.

The display and 10 has the display area 11 provided with the image display function. The display area includes pixels that each emit light of one of the colors RGB and displays full color. Light emission of each pixel is controlled by control signals sent out from the driver IC 24. The display panel 10 according to this embodiment is a liquid crystal display panel. The display panel 10 is not limited to a liquid crystal display panel and may be an organic electroluminescent (EL) display panel or a quantum dot display panel.

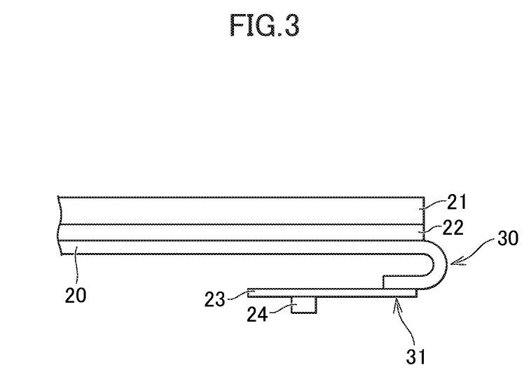

The display panel 10 according to this embodiment is folded back on itself along the return line A and away from the visible side of the display area 11. FIG. 3 is a side view of the display panel 10 according to the first embodiment of the present invention. The first insulating substrate 20 has a bent portion 30 that is adjacent to an edge of the second insulating substrate 21 and a return portion 31 that is folded back away from the second insulating substrate 21. The flexible printed circuit 23 is disposed on the outer surface of the return portion 31. In addition to the flexible printed circuit 23, an electronic component for driving the display panel 10 can be disposed on the return portion 31.

The display panel 10 according to this embodiment includes liquid crystals 25 filled into the region enclosed by the first insulating substrate 20, the second insulating substrate 21, and the sealant 22. The orientation of the liquid crystals 25 is electrically controlled by pixel electrodes disposed in the first insulating substrate 20 to pass polarized light entering from the first insulating substrate 20 through themselves or to change the polarization. To precisely control the orientation of the liquid crystals 25, at is important to keep the distance (cell gap) between the first insulating substrate 20 and the second insulating substrate 21 constant throughout the display area 11.

In the display panel 10 according to this embodiment, the first insulating substrate 20, which is a flexible substrate, allows an edge of the display panel 10 to be folded back on itself to narrow the frame, and the second insulating substrate 21, which is a rigid substrate, reduces strain of the display area 11. Reduction of strain of the display area 11 allows the cell gap of the liquid crystals 25 to be kept uniform throughout the display area 11, thus providing high image display quality.

Also in the display panel 10 according to this embodiment, the return portion 31, on which an electronic component required to drive the display panel 10 is disposed, allows the electronic component to be located outside the frame area, thus narrowing the frame.

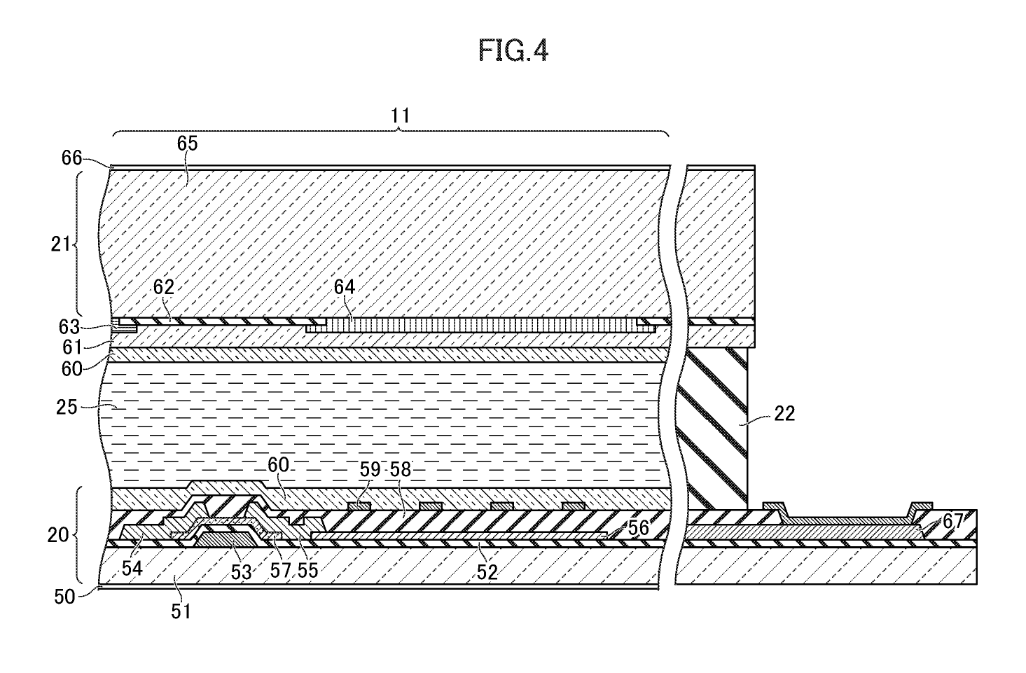

FIG. 4 is a cross-sectional view of the display panel 10 according to the first embodiment of the present invention. A cross section of the display area 11 is shown on the left side of FIG. 4, and a cross section of the area outside the sealant 22 is shown on the right side of FIG. 4. In the display area 11, a first polarizing plate 50 and a second polarizing plate 66 are so arranged that the first polarizing plate 50 passes first polarized light through itself and that the second polarizing plate 66 passes second polarized light orthogonal to the first polarized light, through itself. On the first polarizing plate 50, an insulating substrate 51 made of, for example, polyimide is disposed. On the insulating substrate 51, gate electrode 53 formed of a conductive material, including metal. A gate insulating film 52 is then formed over the insulating substrate 51 and the gate electrode 53. Over the gate electrode 53, a channel layer 57 is formed of, for example, polysilicon on the gate insulating film 52. On the gate insulating film 52, a pixel electrode is also formed of a transparent conductive material, such as indium tin oxide (ITO). A drain electrode 54 and a source electrode 55 are made of a conductive material, including metal, and spaced apart from each other so as to each cover an edge of the channel layer 57. One edge of the source electrode 55 covers an edge of the pixel electrode 56 so that the source electrode 55 and the pixel electrode 56 are electrically coupled to each other. An interlayer insulating film 58 is formed of a silicon nitride film so as to cover each electrode, a comb-shaped common electrode 59 is formed of a transparent conductive material, such as ITO, and a lower alignment film 60 is then formed. The first insulating substrate 20 is thus formed. Although FIG. 4 illustrates a structure of a bottom-gate TFT, the TFT may alternatively be a top-gate TFT The channel layer 57 may be formed of a semiconductor layer made of amorphous silicon or an oxide semiconductor, other than polysilicon.

Right above the lower alignment film 60, an upper alignment film 60 is formed. The gap between the lower and upper alignment films 60 is filled with the liquid crystals 25, and the alignment films 60 and the liquid crystals 25 are sealed around their periphery by the sealant 22. On the upper alignment film 60, an overcoat layer 61 is formed of a resin material. In the overcoat layer 61, a black matrix 62, a blue color filter 63, and a red color filter 64 are formed. In addition to these, although not shown, a green color filter is formed, and thus RGB pixels are formed. Moreover, a counter substrate 65 provided with the second polarizing plate 66 is stacked on the black matrix 62 and each color filter. The second insulating substrate 21, which is disposed on the liquid crystals 25, is thus formed.

Outside the sealant 22 (outside the display area 11), a lead. 67 is formed of metal on the gate insulating film 52 and is joined to the above-described flexible printed circuit 23. The lead 67 transmits electrical signals from the driver IC 24 and applies a power supply potential to the flexible printed circuit 23.

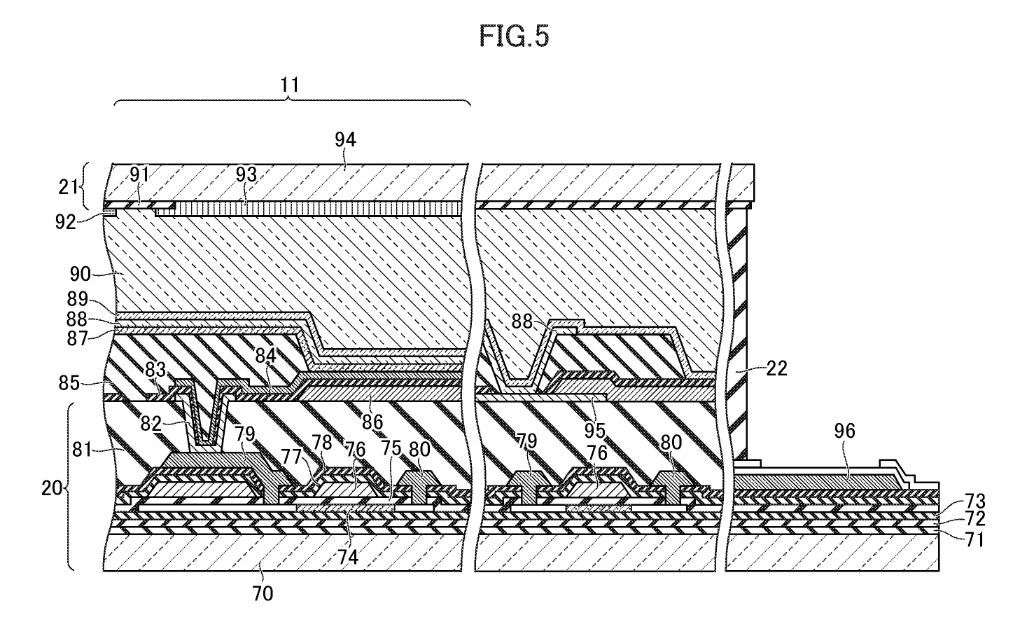

FIG. 5 is a cross-sectional view of a display panel according to a modification of the first embodiment of the present invention. The display panel according to the modification is an organic EL display panel. In FIG. 5, a cross section of the display area 11 is shown on the left side, a cross section of the area between the display area 11 and the sealant 22 is shown in the middle, and a cross section of the area outside the sealant 22 is shown on the right side. For the display panel according to the modification, a first insulating film 71 formed of a silicon oxide film, a second insulating film 72 formed of a silicon nitride film, a third insulating film 73 formed of a silicon oxide film are sequentially stacked on the insulating substrate 70 made of, for example, polyimide. A channel layer 74 is then formed of, for example, polysilicon. A gate insulating film 75 is formed on the channel layer 74. Over the channel layer 74, a gate electrode 76 is formed of a conductive material, including metal, on the gate insulating film 75. A fourth insulating film 77 and a fifth insulating film 78 are sequentially stacked to cover the gate electrode 76. Through holes are formed through the gate insulating film 75, the fourth insulating film 77, and the fifth insulating film 78 to the channel layer 74. A source electrode 79 and a drain electrode 80 are then formed of a conductive material, including metal, so as to be electrically coupled to the channel layer 74 through the through holes. Additionally, a planarization film 81 is formed of, for example, a photosensitive acrylic resin on the source electrode 79 and the drain electrode 80. The first insulating substrate 20 according to the modification is thus formed. Although FIG. 5 illustrates a structure of a top-gate TFT, the TFT may alternatively be a bottom-gate TFT as shown in FIG. 4. The channel layer 57 may be formed of a semiconductor layer made of amorphous silicon or an oxide semiconductor, other than polysilicon.

A through hole is formed through the planarization film. 81 to the source electrode 79. A contact electrode 82 is then formed of a conductive material, including metal, so as to be electrically coupled to the source electrode 79 through the through hole. On the planarization film 81, a capacitor electrode 86 is formed of a conductive material, including metal. A sixth insulating film 83 is formed to cover both the contact electrode 82 except for its bottom and the capacitor electrode 86. A lower electrode 84 is then formed of a conductive material, including metal, so as to be electrically coupled to the source electrode 79 via the contact electrode 82. An inter-pixel insulating film 85, which is an insulating film, is formed to cover part of the lower electrode 84. The area where the inter-pixel insulating film 85 is formed is to be a non-light-emitting area, whereas the area where no inter-pixel insulating film 85 is formed and where the lower electrode 84 is formed is to be a light-emitting area.

On the inter-pixel insulating film 85 and the lower electrode 84, an organic layer 87 including an organic light-emitting layer that emits white light is formed. In this modification, the organic layer 87 is formed throughout the display area 11, but an organic layer may be colored, for each pixel, to emit red, green, or blue light. On the organic layer 87, an upper electrode 88 is formed of a transparent conductive material, such as ITO or indium zinc oxide (IZO). The lower electrode 84, the organic layer 87, and the upper electrode are a light-emitting element (organic EL element) including an organic light-emitting layer, which is stacked on the display area 11. On the upper electrode 88, a seventh insulating film 89 is formed, and a sealing film 90 is then formed. Right above the inter-pixel insulating film 85, a black matrix is formed on the sealing film 90. Right above the light-emitting area, a blue color filter 92 and a red color filter 93 are also formed on the sealing film 90. Although not shown, a green color filter is also formed, and thus pixels that have luminescent colors of RGB are formed. On the black matrix 91, the blue color filter 92, and the red color filter 93, a counter substrate 94 is formed of, for example, glass in this modification, the counter substrate 94 is the second insulating substrate 21.

Outside the display area 11, the upper electrode 88 and the contact portion of a ground electrode 95 as well as the TFT are formed. The upper electrode 88 is maintained at a potential (ground potential) common to all the pixels. Outside the sealant 22, a lead 96 is formed of metal on the fifth insulating film 78 and is electrically coupled to the flexible printed circuit 23 at an area not shown.

### Second Embodiment

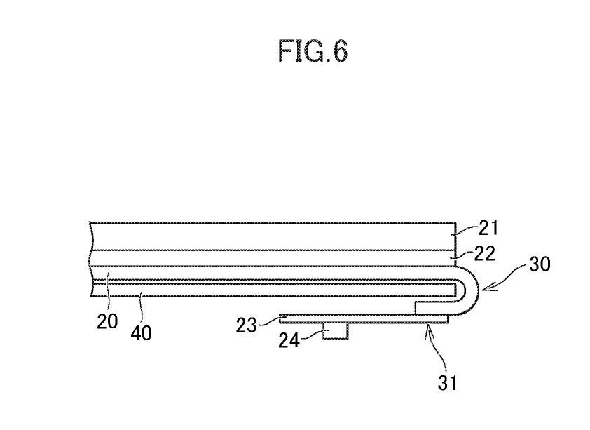

FIG. 6 is a side view of a display panel according to a second embodiment of the present invention. The display panel according to this embodiment includes a backlight 40 disposed to be sandwiched between the surface opposite the visible side of the display area 11 and the inner surface of the return portion 31. The backlight 40 includes light-emitting diodes (LEDs) that emit white light, or cold cathode fluorescent lamps. The configuration of the display panel according to this embodiment is otherwise the same as the configuration of the display panel 10 according to the first embodiment.

The display panel according to this embodiment, in which the backlight 40 is disposed on the side opposite to the visible side of the display area 11, makes use of the space inside the bent portion 30 to form the liquid crystal display device without increasing the thickness of the display panel.

### Third Embodiment

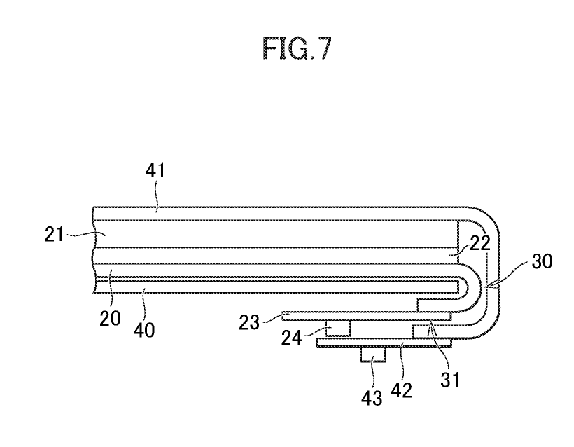

FIG. 7 is a side view of a display panel according to a third embodiment of the present invention. The display panel according to this embodiment includes the backlight 40 and a touch screen 41. The second insulating substrate 21 has a touch detection electrode on at least one of its surface near the first insulating substrate 20 and its opposite surface. The configuration is otherwise the same as that of the display panel 10 according to the first embodiment in this embodiment, the touch screen 41 has a touch detection electrode on its surface near the visible-side of the display area 11. The second insulating substrate 21 has the touch detection electrode on the surface, opposite to the surface near the first insulating substrate 20, near the visible-side of the display area 11. The touch screen 41 performs touch detection based on a change in capacitance between the touch detection electrodes which occurs when, for example, someone's finger closely approaches part of the touch screen 41.

A touch screen flexible printed circuit 42 is electrically coupled to an edge of the touch screen 41 according to this embodiment, and a touch screen driver IC 43 is mounted on the touch screen flexible printed circuit 42. The touch screen 41 is folded back to cover the return portion 31, at the same position as the bent portion 30. The touch screen flexible printed circuit 42 is disposed over the flexible printed circuit 23 and the driver IC 24. Use of such a configuration allows even the frame of a display device with a touch screen to have a narrow frame.

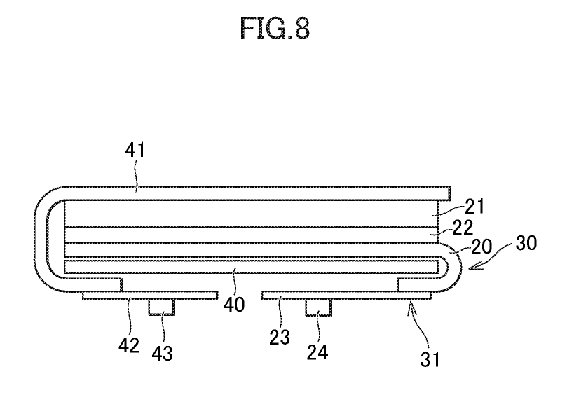

FIG. 8 is a side view of a display panel according to a modification of the third embodiment of the present invention. In this modification, the touch screen 41 is bent back along the side opposite to the side along which the bent portion 30 is located. Bending back the touch screen 41 along the side opposite to the bent portion 30 allows the touch screen flexible printed circuit 42 to be disposed at a position that does not overlap with the return portion 31. The thickness of display panel is reduced by disposing the touch screen flexible printed circuit 12 at a position that does not overlap with the return portion 31.

Those skilled in the art can appropriately modify the design of the display device 1 described above as embodiments of the present invention and implement other display devices, and all such display devices also fall within the scope of the invention as long as they come within the spirit of the invention. For example, two or more sides of the first insulating substrate may be folded back so that the first insulating substrate has a plurality of return portions.

Various variations and modifications can be conceived by those skilled in the art within the spirit of the present invention, and it will be understood that all such variations and modifications also fall within the scope of the invention. For example, those skilled in the art can appropriately modify the above-described embodiments by addition, deletion, or design change of components, or by addition, omission, or condition change of steps, and all such modifications also fall within the scope of the invention as long as they come within the spirit of the invention.

It will also be understood that other effects produced by the aspects described in the embodiments, which are apparent from the description herein or can be appropriately conceived by those skilled in the art, are produced by the present invention as a matter of course.

While there have been described what are at present considered to be certain embodiments of the invention, it will be understood that various modifications may be made thereto, and it is intended that the appended claim cover all such modifications as fall within the true spirit and scope of the invention.

What is claimed is:

1. A display device comprising:
a first substrate being flexible and having a display area provided with an image display function;
a second substrate being smaller than the first substrate and covering the display area; and
a sealant disposed around the display area and fixing the first and second substrates together,
wherein the first substrate has a bent portion adjacent to an edge of the second substrate and a return portion folded back away from the second substrate.

2. The display device according to claim 1, further comprising liquid crystals filled into a region enclosed by the first substrate, the second substrate, and the sealant.

3. The display device according to claim 2, further comprising a backlight disposed to be sandwiched between a surface opposite a visible side of the display area and an inner surface of the return portion.

4. The display device according to claim 1, further comprising a light-emitting element including an organic light-emitting layer, the light-emitting element being stacked on the display area.

5. The display device according to claim 1, wherein an electronic component is disposed on an outer surface of the return portion.

6. The display device according to claim 1, wherein the second substrate is less flexible than the first substrate.

7. The display device according to claim 1, wherein the second substrate is made of glass or a hard resin.

8. The display device according to claim 1, wherein the second substrate has a touch detection electrode on at least one of a surface thereof near the first substrate and an opposite surface thereof.
